(19) United States
(12) Patent Application Publication
(10) Pub. No.: US 2014/0162407 A1
(43) Pub. Date: Jun. 12, 2014

(54) Method And System For Semiconductor Packaging

(71) Applicants: Curtis Michael Zwenger, Chandler, AZ (US); Yoon Joo Kim, Nwong-gu (KR); Brett Dunlap, Queen Creek, AZ (US)

(72) Inventors: Curtis Michael Zwenger, Chandler, AZ (US); Yoon Joo Kim, Nwong-gu (KR); Brett Dunlap, Queen Creek, AZ (US)

(21) Appl. No.: 13/709,414

(22) Filed: Dec. 10, 2012

(51) Int. Cl. H01L 21/56

(52) U.S. Cl. CPC H01L 21/565
USPC 438/113

(57) ABSTRACT

Methods and systems for semiconductor packaging are disclosed and may include bonding a semiconductor wafer to a support structure, separating the wafer into discrete die, removing the die from the support structure, and attaching at least a subset of the die to a second support structure. Mold material may be placed in voids between the die utilizing a compression molding process, thereby generating a molded wafer, which may be demounted before depositing redistribution lines on the die and the mold material. Conductive balls may be placed on the redistribution lines before separating into molded packages. The molded wafer may be planarized utilizing a post-mold cure on a heated vacuum chuck after removing it from the second support structure. The redistribution lines may be electrically isolated utilizing polymer layers. The conductive balls may be placed on copper redistribution lines with a surface oxide layer at least 20 angstroms thick.

### FIELD OF THE INVENTION

Certain embodiments of the invention relate to semiconductor chip packaging. More specifically, certain embodiments of the invention relate to a method and system for semiconductor packaging.

### BACKGROUND OF THE INVENTION

Semiconductor packaging protects integrated circuits, or chips, from physical damage and external stresses. In addition, it can provide thermal conductance path to efficiently remove heat generated in the chip, and also provide electrical connections to other components such as printed circuit boards, for example. Materials used for semiconductor packaging typically comprises ceramic or plastic, and form-factors have progressed from ceramic flat packs and dual in-line packages to pin grid arrays and leadless chip carrier packages, among others.

Further limitations and disadvantages of conventional and traditional approaches will become apparent to one of skill in the art, through comparison of such systems with the present invention as set forth in the remainder of the present application with reference to the drawings.

### BRIEF DESCRIPTION OF SEVERAL VIEWS OF THE DRAWINGS

FIG. 1 is a diagram illustrating a molded wafer comprising a plurality of die, in accordance with an example embodiment of the invention.

FIG. 2 is a flow diagram illustrating a process for making a semiconductor package, in accordance with an example embodiment of the invention.

FIG. 3 is a diagram illustrating a cross-sectional view of a molded package, in accordance with an example embodiment of the invention.

FIG. 4 is a diagram illustrating close-up cross-sectional views of a molded die, in accordance with an example embodiment of the invention.

FIGS. 5A-5E are diagrams illustrating various steps of a wafer reconstitution process, in accordance with an example embodiment of the invention.

FIGS. 5F-5M are diagrams illustrating various steps of a redistribution layer process, in accordance with an example embodiment of the invention.

### DETAILED DESCRIPTION OF THE INVENTION

Certain aspects of the invention may be found in a method and system for semiconductor packaging. Exemplary aspects of the invention may comprise bonding a semiconductor wafer to a support structure, separating the wafer into a plurality of discrete die, removing the plurality of discrete die from the support structure, and attaching at least a subset of the plurality of discrete die to a second support structure. Mold material may be placed in voids between the attached at least a subset of the plurality of discrete die utilizing a compression molding process, thereby generating a molded wafer (also referred to herein as a “reconstituted wafer”), which may then be removed from the second support structure before depositing redistribution lines on the die and the mold material. Conductive balls, or other external interconnect structures, may be placed on at least a subset of the redistribution lines, which may comprise copper, before separating the molded wafer into plurality of molded packages. The molded wafer may be planarized utilizing a post-mold cure on a heated vacuum chuck after removing it from the second support structure. The redistribution lines may be electrically isolated utilizing one or more polymer layers. The polymer layers may comprise polybenzoxazole (PBO) and may be more than 10 microns thick. The conductive balls may be placed on the redistribution lines that comprise a surface oxide layer at least 20 angstroms thick. The conductive balls may comprise solder balls. The mold material may comprise an epoxy mold material. A partial cure of the mold material may be performed during the compression molding process.

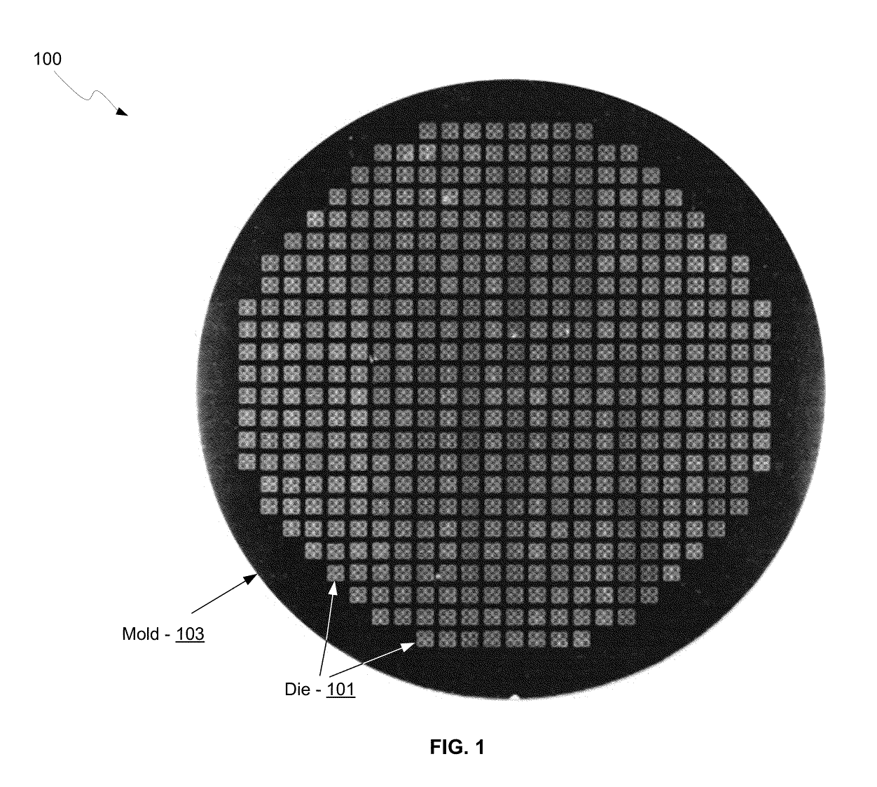

FIG. 1 is a diagram illustrating a molded wafer comprising a plurality of die, in accordance with an embodiment of the invention. Referring to FIG. 1, there is shown a molded wafer 100 comprising mold material 103 and a plurality of die 101.

The die 101 may comprise integrated circuit die that have been separated from a semiconductor wafer and packaged within the mold material 103. The die 101 may comprise electrical circuitry such as digital signal processors (DSPs), network processors, power management units, audio processors, RF circuitry, wireless baseband system-on-chip (SoC) processors, sensors, and application specific integrated circuits, for example.

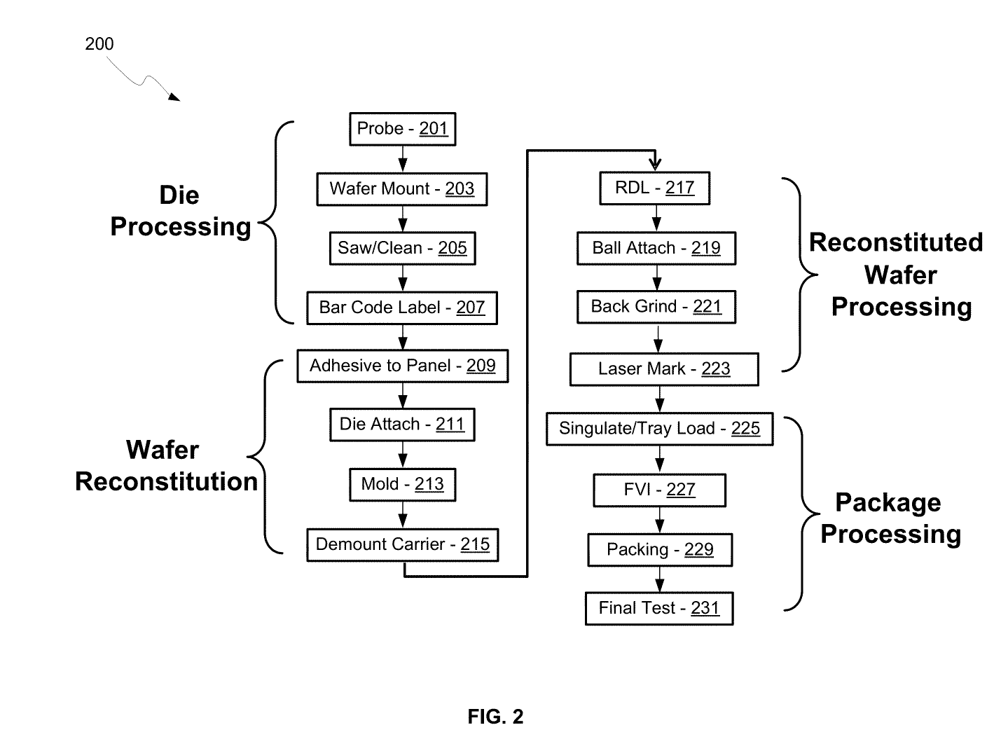

While the semiconductor packaging process (also referred to herein as a wafer level fan-out process) is described further with respect to FIGS. 2-5, the process may be summarized as the dicing of a received semiconductor wafer, mounting the separated die into an array on a support structure with a temperature-sensitive adhesive, filling the gaps between the die using the mold material 103, curing the mold material 103, and separating the resulting molded (or reconstituted) wafer 100 from the support structure.

The mold material 103 may comprise a polymer that may be compression molded at an elevated temperature. The molded wafer 100 may be subsequently processed with the addition of redistribution layers and solder balls to form electrical interconnects from various points in the die 101 to external devices or circuit boards, for example. In an exemplary scenario, the packaged die resulting from the semiconductor packaging process (e.g., a molded wafer fan-out process) may comprise tens to hundreds of I/O interconnects per die.

Redistribution layers and solder balls may be fabricated over the die as well as over the mold material. This semiconductor packaging process may result in larger than die-sized packaging with increased I/O density over conventional packaging techniques, and allows the die pad locations on the chip to be placed in interstitial sites below the solder ball grid array. Furthermore, the semiconductor packaging process enables improved form factors in 3-D structures with the ability to form redistribution layers on both sides of the die and mold material, as well as through silicon vias (TSVs) in the die and/or through mold vias (TMVs) in the mold material. For example, TMVs may provide conductive interconnection pathways that extend through the mold layers discussed herein, and TSVs may provide conductive interconnection pathways that extend through the silicon die discussed herein.

FIG. 2 is a flow diagram illustrating a process for making a semiconductor package (e.g., a wafer level fan-out process), in accordance with an example embodiment of the invention. Referring to FIG. 2, there is shown semiconductor packaging process 200 that comprises a probe step 201, a wafer mount step 203, a saw and clean step 205, and a bar code label step 207. These beginning steps may, for example, be referred to herein as die processing steps. The die processing steps may then, for example, be followed by an adhesive to panel step 209, a die attach step 211, a mold step 213, and a demount carrier step 215. Such steps may, for example, be referred to herein as wafer reconstitution steps.

The wafer reconstitution steps may, for example be followed by a redistribution layer (or RDL) step 217, a ball attach step 219, a back grind step 221, and a laser mark step 223. Such steps may, for example, be referred to herein as reconstituted wafer processing steps. Finally, reconstituted wafer processing steps may be followed by a singulate and tray/tape and reel load step 225, a final visual inspection step 227, a packing step 229, and a final test step 231. Such steps may, for example, be referred to herein as package processing steps.

Turning first to the die processing steps, the probe step 201 may comprise electrical testing of the die circuitry in a wafer to be processed. The wafer may be cleaned and visually inspected prior to probe test, or the probe test 201 may be skipped entirely if the wafer was tested before being received and was supplied with a die map (e.g., a map or listing of known-good die). The probe step 201 may be utilized to determine which die on the received wafer pass performance specifications, so as to avoid the time and expense lost in packaging a bad die. Accordingly, a map of known-good die may be generated in the probe step 201 for subsequent separation of the die into pass/fail groups of die.

The wafer mount step 203 may comprise the mounting of the probe-tested wafer onto a support structure, such as a metal chuck for example. The wafer may be mounted using an adhesive material to enable subsequent dicing of the wafer into multiple pieces comprising the individual die of the wafer. In this manner, die that passed the probe test may be selected for subsequent processing, while those that failed may be removed from the process. The wafer may be thinned utilizing a back grind, if desired. A thinned wafer may be useful for sensing chip applications or in instances when an incoming wafer is thicker than desired for semiconductor packaging processes, for example. A wafer may, for example, be thinned to expose TSVs. A wafer may also, for example, be thinned to provide mold space above the die in the mold cavity into which mold material flows during the molding process.

After the wafer has been mounted onto the support structure, it may, for example at step 205, be sawn into discrete die utilizing a wafer saw, laser, or other die-excising means, and then cleaned utilizing deionized (DI) water, for example. The diced wafer, die, and/or adhesive film may be labeled with one or more bar codes in the bar code label step 207. This may enable subsequent identification of the diced wafer and/or individual die. A visual inspection may be performed after each process step to remove damaged/broken die or those with excessive defects, for example.

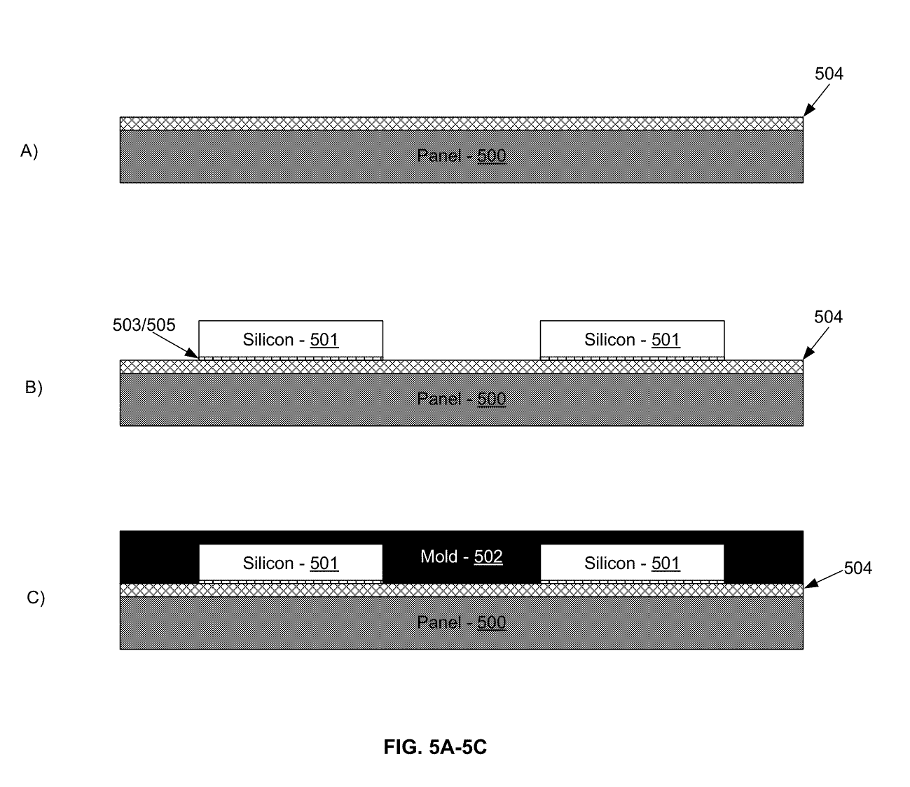

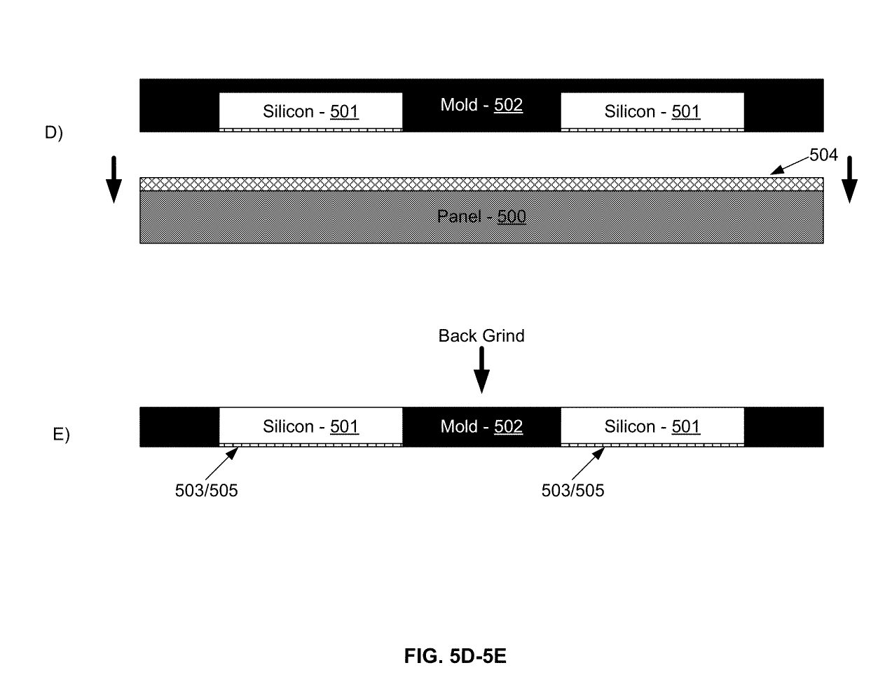

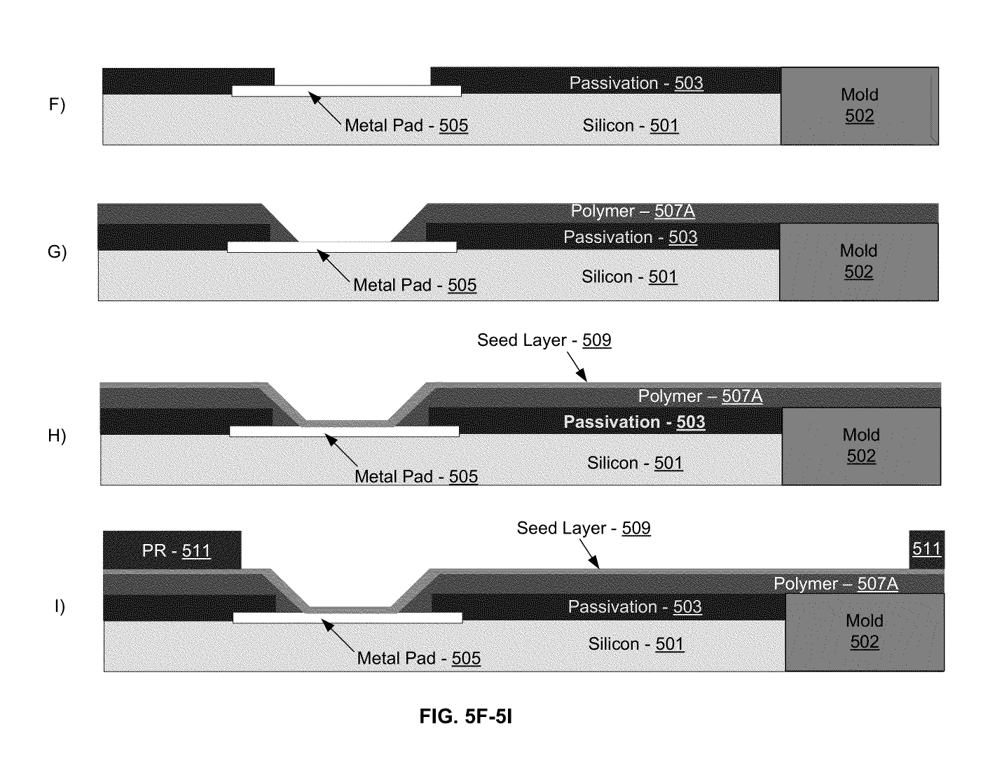

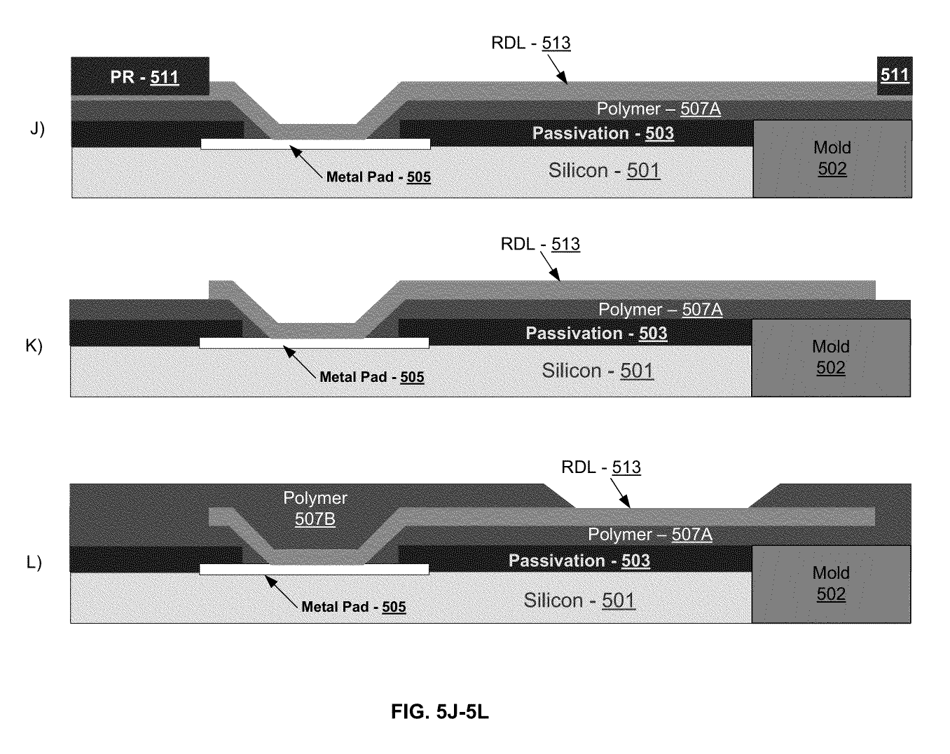

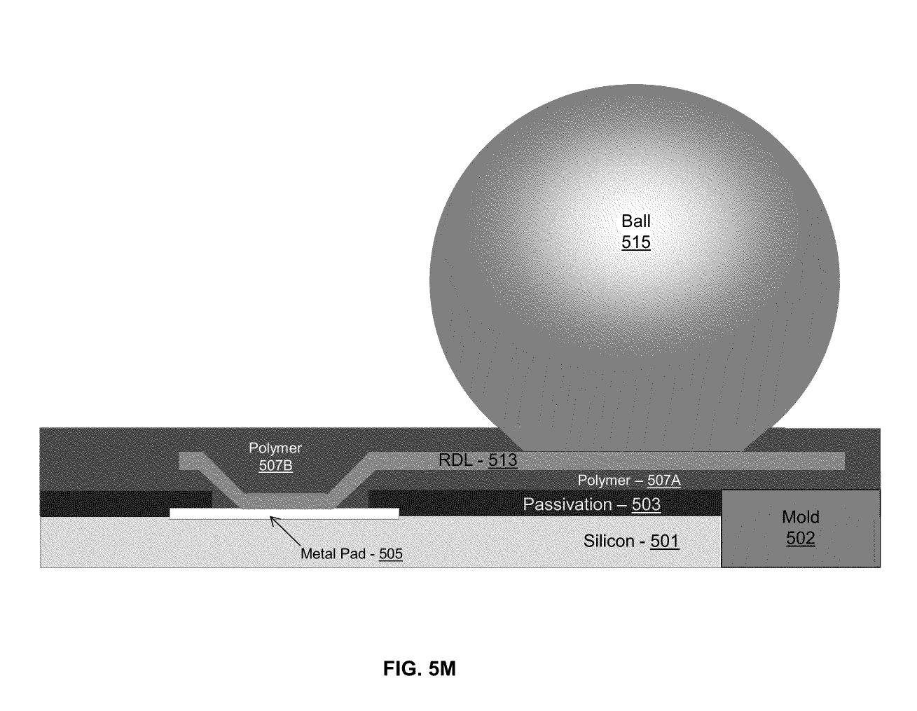

The process 200 may then continue to the wafer reconstitution steps (e.g., forming a molded wafer out of molding material and known-good die), starting with the adhesive to panel step 209, which may comprise the placement of an adhesive material to a panel support structure. A diagram illustrating an example structure corresponding to the adhesive to panel step 209 is shown at FIG. 5A.

The panel 500 may comprise a metal alloy carrier with an appropriate surface smoothness for proper sticking of the adhesive. In an example scenario, the panel 500 may exhibit a surface roughness of less than 2 microns and may have dimensions similar in size to a standard semiconductor wafer diameter, such as 200 or 300 mm, depending on the process equipment diameter requirements. The panel 500 may, for example, be polished in a particular direction to assist with later removal of the adhesive film from the panel. The panel 500 may, for example, comprise an anodized surface. In an exemplary scenario, the panel 500 may comprise alloy 42 or 52 steel that may be operable to withstand large temperature variations without warping and exhibit minimal surface corrosion over time. The panel 500 may, for example, comprise various features (e.g., registration features, keying features, etc.) to assist in downstream processes, for example with wafer and/or tooling alignment.

The adhesive material 504 (e.g., adhesive film) may comprise a temperature sensitive double-sided tape, for example, that may be utilized to attach the die (e.g., the die singulated at step 205) to the panel 500. The adhesive material 504 may be configured to stick to one or more surfaces by heating to a desired temperature with a force applied for a specific time, each factor being adjusted for the adhesive material utilized. An exemplary adhesive material 504 is Nitto Denko REVALPHA thermal release tape comprising foaming adhesive, polyester film, and a base adhesive sandwiched between liner layers, with a peeling temperature of 170 degrees C. In an exemplary scenario, the layer stack may comprise a ˜75 micron polyester liner, a ˜10 micron base adhesive, ˜ a ˜40 micron polyester file, a ˜50 micron foaming adhesive, and a ˜40 micron polyester liner.

The structure may then be cooled below the bonding temperature for subsequent processing. The adhesive material 504 may withstand changes in temperature while retaining adhesiveness at high temperatures during subsequent processing (e.g., molding). Also, the adhesive material 504 may withstand compression under load, such as during subsequent die-attaching (211) and/or molding (213) steps. For example, during such compression, it may be desirable for die mounted to the adhesive material 504 (e.g., at die attach step 211) to penetrate the plane of the adhesive material 504 as little as possible, ultimately providing for coplanarity between the die surface and mold surface. Such penetration, resulting in a planar discontinuity between the die and mold materials, might or might not be desirable. For example, as illustrated in FIG. 5B, the top surface of the adhesive material 504 and the bottom surfaces of the silicon die 501 may be generally coplanar if the die 501 minimally penetrate the top surface of the adhesive material 504 during die placement. Additionally, the adhesive material 504 may be demountable from the panel 500 and attached die 501 without leaving any residue on the surfaces.

In the die attach step 211, selected die may be attached to the adhesive on the panel, and may be placed in an array that will form the molded wafer, as described with respect to FIG. 1. A diagram illustrating an example structure corresponding to the die attach step 211 is shown at FIG. 5B.

The silicon die 501 may be selected, for example based on a known-good die map made at the probe step 201 or received with the original wafer. Accordingly, the wafer reconstitution process may result in a reconstituted molded wafer with only known good die (e.g., as opposed to an original wafer, which might only have a 60-99% yield). The number of die attached to the adhesive material 504 may be determined by the die size in relation to the panel 500, by the desired semiconductor package dimensions, by buffer space allocated for the singulation process, etc. For example, up to several thousand die 501 may be attached to the panel 500 for smaller die sizes and as few as ˜10 die 501 may be attached for larger die sizes.

In an exemplary scenario, the die 501 may be placed with the electronics side (or active side) toward the adhesive material 504, and placed at a pressure of 300 grams, for example, with the panel 500 temperature set for desired adhesiveness. As shown at FIG. 5B, the silicon die 501 may comprise passivation layers 503 and metal pads 505 on the side affixed to the adhesive film 504.

During the subsequent mold step 213, the die may move slightly on the surface of the adhesive, with the amount of skew, which may be on the order of a few microns up to ˜20 microns or more. Such movement may, for example, comprise rotational and/or translational components. Such movement may, for example, be a function of the radial distance of the die from the center of the reconstituted wafer, the die size, the die aspect ratio, die spacing, die thickness, adhesion strength of the adhesive, mold material and/or pressure, etc. This movement may, for example, be generally consistent from wafer-to-wafer for a given product, and may be characterized such that subsequently placed die may be placed with a known offset (e.g., a rotational and/or translational offset) to compensate for the expected shift. For example, if a particular die is anticipated to shift xyθ during the molding process, the die may be placed at the desired location and orientation less xyθ before the molding process.

The amount of shift may be assessed in a visual inspection before subsequent processing. Such amount of shift may, for example, be stochastically characterized over a number of production runs to a desired level of statistical certainty. Such amount of shift may also be routinely tracked over time to compensate for process variability, both long and short term. In an exemplary implementation, such amount of shift may be generally consistent from wafer quadrant to quadrant, such that characterization of shifting for a single quadrant may efficiently be applied to the remaining three quadrants. In an exemplary implementation, the amount of rotational shift of die in the molded wafer may be controlled to a 0.3 degree certainty, 0.1 degree certainty, or 0.2 degree certainty. Such control may, for example, be necessary or at least desirable for subsequent processing steps (e.g., masking steps involving a template overlay or reticles for stepping).

The mold step 213 may comprise the filling of the space between the die that have been attached to the adhesive material on the panel. A diagram illustrating an example structure corresponding to the mold step 213 is shown at FIG. 5C.

The mold material 502 may be incorporated by placing a wafer-shaped enclosure around the die 501 attached to the panel 500 and inserting mold material, which may be in pellet, granular, powder, or liquid form. If in solid form, the panel 500 and die 501 structure may be shaken or vibrated to reduce or eliminate voids in the mold material 502 upon curing. A mold compression structure, for example a mold chase may then be placed at or near the surface of the attached die 501 and panel 500. The mold material 502 may cover the surface of the die 501 in instances when the chase is offset from the die 501, or mold material 502 may only fill the void between the die 501 and not cover the top surface of the die 501 when the plunger (or a seal coupled thereto) makes contact with the top surface of the die 501. In an exemplary implementation, the mold chase height may be adjustable and set at a height of up to ˜1.5 mm, for example, generally providing for molding compound 502 to completely cover (at least until removed) the surface of the die 501 that is exposed to the mold compound 502 (e.g., generally the passive side of the die 501 with the active side facing the adhesive layer 504).

The mold material 502 may comprise characteristics of any of a variety of different types of mold material. For example and without limitation, the mold material 502 may be an epoxy mold material with a spherical filler shape, with a maximum filler size of approximately 30 microns and filler content of ˜80% by volume, ˜90% by weight. The mold material 502 may be cured, at least partially, at an elevated temperature while under pressure from the plunger mechanism. In an exemplary scenario, the cure temperature may be ˜120-180 C. In an exemplary scenario, the mold material 502 shrinkage may be less than +/−0.20% and exhibit flexural modulus of ˜10-30 GPa and flexural strength of ˜5-30 MPa. Additionally, the mold material 502 may exhibit a disk flow of ˜60-120 mm, for example.

The mold step 213 may, for example, comprise forming features (e.g., in the molding material) to enhance manufacturability and/or quality. For example, step 213 may comprise the formation of registration features such as alignment or fiducial keys in the reconstituted wafer that can be utilized for mechanical and/or visual determination of location and/or orientation. Such molded features may, for example, mate with features in downstream tooling for alignment. Also, such molded features may, for example, enhance the handling and/or restraining of the molded wafer. Additionally, such molded features may enhance later singulation operations. Furthermore, subsequent processing steps may add further alignment keys based on the original key or keys formed in the molded wafer. Furthermore, subsequent processing steps may add further alignment keys, for example based on the original key or keys formed in the reconstituted wafer.

A back grind may, for example in preparation for the reconstituted wafer processing steps discussed below, be utilized after a mold cure process to remove mold compound, for example from an exposed die surface, if desired. Such back grind may, for example in addition to reducing reconstituted wafer thickness, reduce warpage in the reconstituted wafer. For example, in an exemplary implementation, such warpage may be less than 2 mm (or, e.g., less than 1 mm) of planar deviation across the surface of the entire molded wafer.

The resulting reconstituted wafer (or molded wafer) structure comprising the mold material 502 and attached die 501 may then be demounted in the demount carrier step 215. A diagram illustrating an example demount carrier step 215 is shown at FIG. 5D, which shows removal of the reconstituted wafer (e.g., comprising the silicon die 501 and mold material 502) from the panel 500.

The demount carrier step 215 may, for example, comprise heating the panel 500 and adhesive material 504 to a demount temperature, where the adhesive material 504 may thus be removed from both the panel 500 and the reconstituted wafer at a desired speed and force.

In an example scenario, a back grind step may be executed after the demount carrier step 215 and before the redistribution layer step 217. A reconstituted wafer resulting from such a back grind step is illustrated at FIG. 5E.

A proper adhesive material 504 will not leave residue on the panel 500 or the reconstituted wafer (e.g., including the silicon die 501 and the mold material 502) upon demount (e.g., when properly removed). For example, as mentioned previously, the panel 500 may be polished in a particular direction, thus resulting in a preferred direction of adhesive material 504 (e.g., adhesive film) removal.

The resulting reconstituted wafer may, for example, be mounted to a vacuum fixture comprising a heating plate with vacuum capability for a post-mold cure, which may reduce or eliminate any warpage in the reconstituted wafer. Such warpage may be affected by the die spacing, die thickness, die aspect ratio, and wafer thickness, for example. The post-mold cure may be at a lower temperature, such as 150 C, but for a longer time than the in-mold cure. The post-mold cure may, for example, be performed in a batch process in an oven.

Following the demount carrier step 215 and an optional back grind step, the reconstituted wafer may continue to the reconstituted wafer processing steps, the first of which is the redistribution layer step 217, where one or more metal interconnect layers may be formed on one or more surfaces (e.g., a top surface) of the reconstituted wafer, which comprises both the die and the cured mold material. In general, the redistribution layers may comprise a suitable conductive material, such as copper, for example, that may provide redistribution lines, or interconnects, between points on the die to ball bonds that may lie on top of the die as well as over the mold material.

In an example scenario, multiple redistribution layers may be deposited to create redistribution lines, and as such may comprise 3-dimensional structure. For example, multiple redistribution layers may be utilized to create redistribution lines that interconnect in horizontal and vertical directions. In this manner, a plurality of die may be coupled utilizing redistribution lines in a lateral configuration and/or in a vertical, or stacked, configuration.

The redistribution layers, and thus redistribution lines, may be insulated from each other and the die utilizing a dielectric material, such as a polyimide or other polymer (e.g., polybenzoxazole (PBO). The polymer layers may be a few microns to over 10 microns thick, for example. In this manner, a higher density of interconnects may be made to the die in the molded wafer compared to conventional fan-outs.

Diagrams illustrating an example redistribution layer step 217 are shown at FIGS. 5F-5L, which will now be discussed.

Referring to FIG. 5F, there is shown a molded wafer structure comprising the silicon die 501, the mold material 502, a passivation layer 503, and a metal pad 505. This structure may comprise the input to the semiconductor packaging process steps 217 and 219 in FIG. 2, where the incoming wafer has been sawn into separate die and the good die have been fabricated into a molded wafer.

The metal pad 505 may comprise an exemplary metal contact for the circuitry in the silicon die 501, which may comprise hundreds of similar contact pads across each die in the molded wafer, the number of which may depend on the desired number of I/O's for each die.

The passivation layer 503 may cover the silicon die 501 and part of the metal pad 505, and may comprise an insulating layer, such as silicon dioxide or silicon nitride, for example. This layer may provide mechanical protection for the underlying silicon die 501 and provide electrical insulation between the die 501 and the conductive layers and solder balls subsequently deposited on the die 501. Prior to performing the additional processing below, the reconstituted wafer may be cleaned by one or more processes. For example, the reconstituted wafer may be run through a surface clean descum process, utilizing an oxygen plasma to remove organic film from the surface. Also for example, the reconstituted wafer may be run through a spin rinse dry process, utilizing a DI water spray followed by a nitrogen dry to remove mechanical particles.

Referring next to FIG. 5G, a layer of polymer (e.g., a polymer like PBO with a curing temperature of less than 250 degrees C. (e.g., 230 degrees) or a polymer with a curing temperature of less than 300 degrees C., with the desired planarization characteristics) may be spun on to the molded wafer comprising the silicon die 501 to define the polymer layer 507A. A material (e.g., a polymer) with a curing temperature at or below the glass transition temperature of the mold compound may provide various advantages, such as maintaining the material integrity of all wafer materials and bonds therebetween during the curing process. The thickness of the resulting polymer layer may depend on factors such as the viscosity of the polymer and the spin speed during application, for example. The thickness may, for example, be greater than 10 microns (e.g., 12 microns). Photolithography processes may then be used to define a window over the metal pad 505 for subsequent redistribution layer contact. Accordingly, the coated wafer may then be cured at an elevated temperature that is determined by the normal cure temperature for the polymer. Once cured, the wafer may be exposed to ultraviolet light under a mask or via a stepper followed by a develop step.

In instances where a positive polymer is used to obtain a sloped polymer layer at the opening, as shown in FIG. 5G, the exposed polymer may be removed in the developer. A second cure may then be performed to harden the remaining polymer before performing a descum operation on the wafer followed by a DI water rinse in a spin/rinser/dryer (SRD). The descum operation may, for example, utilize an oxygen plasma to clean the surface, for example removing polymer scum in vias, and also to roughen the surface to provide better metal adhesion in a subsequent process step.

The resulting structure may be coated with a thin metal layer or layers, resulting in the seed layer 509 as shown in FIG. 5H. In an exemplary scenario, the seed layer 509 may comprise thin layers of sputtered titanium, tungsten, and copper (e.g., a TiW layer and a Cu layer), although other metals and deposition techniques may be utilized. In an exemplary scenario, the thickness of the seed layer 509 may be on the order of 1000-5000 Angstroms.

A second photoresist process comprising photoresist spin on, bake, mask expose, develop, and descum may then be utilized to define a region to be coated with copper for a redistribution layer, as shown in FIG. 5I. The resulting photoresist layer 511 may thus define where copper may be selectively deposited for the redistribution layer on the molded wafer, as shown over the silicon die 501 and mold material 502 in FIG. 5J. The deposited copper layer may be on the order of 9 (or 8-10) microns thick, where the resulting redistribution layer 513 comprises the deposited copper and the thin seed layer 509 shown in FIGS. 5H and 5I.

The photoresist may then be stripped and the exposed region of the seed layer 509 may be etched, resulting in the structure shown in FIG. 5K. In an exemplary scenario, the seed layer etch may comprise a copper etch followed by a titanium/tungsten etch, although other etch processes may be utilized for other metal combinations. The etch process may be followed by a descum process and an optional acetic acid clean or DI SRD process. Though an acetic acid cleaning step might be incorporated at this point to remove oxidation from the copper, in the present example, such a step may be skipped, or for example only include a DI rinse, thus intentionally leaving behind some oxidation on the copper. Such oxidation may be at least 20 Angstroms thick, for example, and may provide for better adhesion with a subsequent layer (e.g., a next PBO layer).

The etched structure may then be coated with a second polymer layer 507B (e.g., approximately 12 microns of PBO, over 10 microns of PBO, etc.), and subsequently processed with mask alignment and expose, develop, cure, and descum photolithography techniques to form an opening over the desired solder ball location, resulting in the structure shown in FIG. 5L. In this manner, an electrically isolated redistribution layer may be formed from the metal contacts in the silicon die 501 to solder balls for connection to external boards or devices. One of more cleaning processes may be performed at this time. As discussed above, though an acetic acid cleaning step might be incorporated at this point to remove oxidation from the copper, in the present example, such a step is skipped, or for example replaced with a descum step and a DI rinse, thus leaving behind some oxidation on the copper.

Prior to solder ball placement, flux may be placed (e.g., printed) at each solder ball location. Such fluxing may, for example, be particularly helpful when the above-mentioned acetic acid cleaning step has been skipped. Such flux may, for example, comprise a no-clean flux that may be more compatible with the PBO material than other types of flux (e.g., water-soluble flux).

Turning back to FIG. 2, after the redistribution layer step 217, solder balls (or other package attachment structures) may be placed on the molded wafer at contact points defined by the redistribution layers at ball attach step 219. A diagram illustrating an example structure corresponding to the ball attach step 219 is shown at FIG. 5M.

In general, the solder balls (or other conductive attachment structures) may provide electrical contacts to external structures such as printed circuit boards. The solder balls may be placed directly on the redistribution layers or with an intermediate contact layer. The solder ball placement may coincide with interstitial spaces surrounding the contact vias to the underlying die to avoid possible short circuits and capacitive coupling. Referring to FIG. 5M, solder balls 515 (or other package attachment structures) may be attached to the silicon die 501 and/or the mold material 502, resulting in the structure shown in FIG. 5M. The solder ball 515 may be placed directly on the redistribution layer 513, where the redistribution layer 513 may be thick enough to preclude the need for under bump metal under the solder ball 515. The solder ball 515 may be subjected to a reflow process at an elevated temperature to create a low resistance, and mechanically sound, contact between the solder ball 515 and the redistribution layer 513. This structure may comprise the result of the redistribution layer 217 and ball attach step 219 described with respect to FIG. 2.

The structure may then be processed by one or more cleaning processes, for example a flux clean process. In an exemplary implementation in which no-clean flux is used for solder ball attachment, any remaining residue may still be cleaned utilizing any of a variety of solvents. Such cleaning may, for example, be visually advantageous (e.g., assisting in a subsequent visual inspection process).

Turning back to FIG. 2, the back grind step 221 may comprise an optional step for grinding the back surface of the reconstituted wafer to reduce the thickness of the desired structure. This may be useful in sensor applications, for example, where optical absorption in the die substrate may reduce sensor performance. The thinned reconstituted wafer may then be cleaned and visually inspected.

The final step of the reconstituted wafer processing steps may include the laser mark step 223, where the reconstituted (or molded) wafer and/or the individual die of such wafer may be laser marked for identification purposes. The laser may, for example, mark die material and/or mold material. In an exemplary scenario, a probe test may be performed on the reconstituted wafer at this point, where the reconstituted wafer can be probe tested just as an as-received wafer may be tested.

The package processing steps may begin with the singulate and tray load step 225. In this step, the reconstituted wafer may be separated into individual molded packages utilizing a saw, laser, and/or other cutting technique and loaded into trays or tape and reel for transport. The final visual inspection step 227 may comprise an inspection for defects in the resulting structure, followed by the packing step 229 where the inspected molded packages may be packed for final test and shipping. The final test step 231 may comprise electrical tests of the contacts from the solder balls (or other semiconductor package attachment structure) to the circuitry in the die via the redistribution layers.

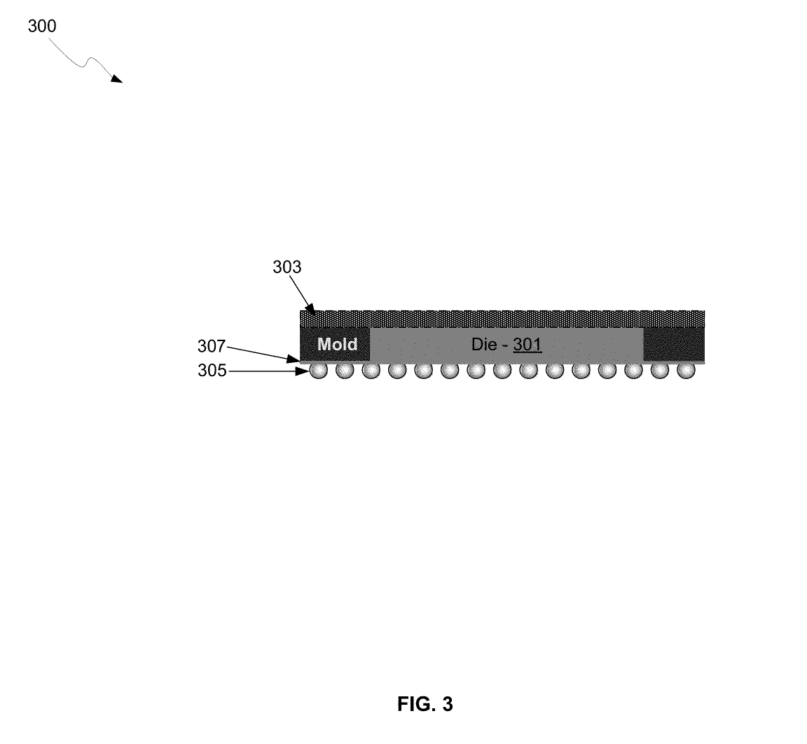

FIG. 3 is a schematic illustrating a cross-sectional view of a molded package, in accordance with an embodiment of the invention. Referring to FIG. 3, there is shown a molded package 300 comprising a die 301, mold material 303, solder balls 305, and redistribution layers 307. The molded package 300 represents a structure resulting from the semiconductor packaging process 200 described with respect to FIG. 2. The solder balls 305 are shown in a regular array across the molded package 300, although the invention is not so limited. Any pattern of solder balls 305 may be configured across the surface of the molded die 300, depending on the desired number of I/O's and the molded package 300 surface area.

The mold material 303 may surround the entire edge of the die 301, providing both mechanical support for the die 301 and surface area for redistribution layers and the solder balls 305. In another exemplary scenario, the mold material 303 may also be placed on the top surface of the die 301, as illustrated by the dashed line mold material shown in FIG. 3. If a bare top surface of the die 101 is desired, the mold material 303 may be removed in a grinding process, for example. In an exemplary scenario, the molded package 300 may be on the order of a square centimeter, but may be any size as determined by the die size and the desired die to package size ratio. In an exemplary scenario, the die 301 may be co-designed with the package 300 to allow for a single metal layer redistribution layer 307 for connecting to the solder balls 305.

The compression molded packaging illustrated by the molded package 300 may exhibit improved board-level and component-level reliability with respect to thermal cycling and physical shock, with high yields on test packages even after thousands of thermal cycles and hundreds of drop tests.

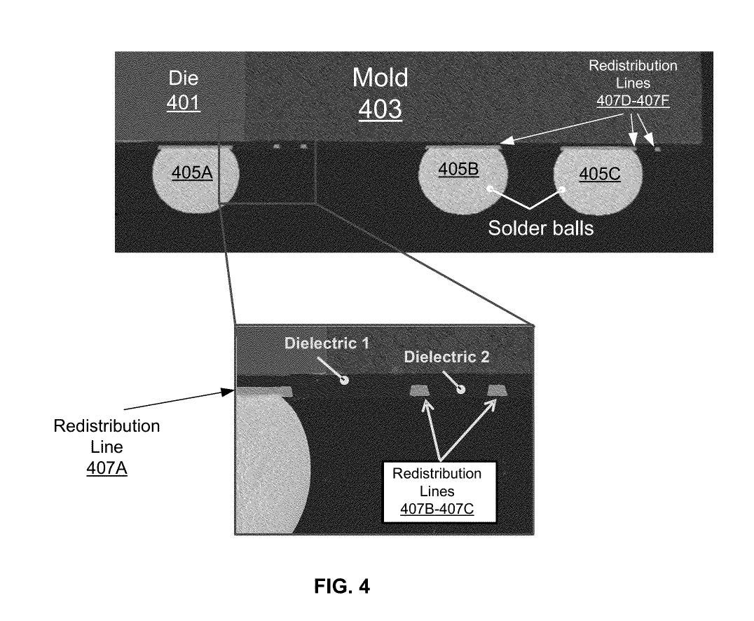

FIG. 4 is a schematic illustrating close-up cross-sectional views of a molded die, in accordance with an embodiment of the invention. Referring to FIG. 4, there is shown close-up views of a molded die comprising a die 401, mold material 403, solder balls 405A-405C, and redistribution layers 407A-407F. The top image shows a lower magnification view of the structure illustrating the width of the mold material 403 and part of the width of the die 401 with respect to the placement of the solder balls 405A-405C.

The lower image shows a higher magnification view of the redistribution layer 407A-407C and the insulating layers surrounding the redistribution lines 407A-407C, Dielectric 1 and Dielectric 2, corresponding to the polymer layers described with respect to FIG. 2.

FIG. 4 illustrates the ability to place redistribution lines and solder balls on both the mold material 403 and on the die 401, as shown by the redistribution lines 407A-407F, which extend into the plane of the image. This greatly improves the available input/output (I/O) density for the die 401, enabling smaller package dimensions while still retaining a high I/O count. Similarly, the compression molded package (e.g., generally die-sized or slightly larger than die-sized) enables greater flexibility in I/O placement in the package.

In an embodiment of the invention, a method and system are disclosed for a wafer level fan-out. In this regard, aspects of the invention may comprise bonding a semiconductor wafer to a support structure, step 203, separating the wafer into a plurality of discrete die 101, step 205, removing the plurality of discrete die from the support structure, and attaching at least a subset of the plurality of discrete die 101 to a second support structure, panel in step 209. Mold material 104, 403 may be placed in voids between the attached at least a subset of the plurality of discrete die 101 utilizing a compression molding process, step 213, thereby generating a molded wafer 100, which may then be removed from the second support structure before depositing redistribution lines 407A-407C, 513 on the die 401 and the mold material 403.

Conductive balls 305, 405A-405C, 515 may be placed on at least a subset of the redistribution lines 407A-407C, 513 which may comprise copper, before separating the molded wafer 100 into plurality of molded packages 300. The molded wafer 100 may be planarized utilizing a post-mold cure on a heated vacuum chuck after removing it from the second support structure, step 215. The redistribution lines 407A-407C may be electrically isolated utilizing one or more polymer layers 507A, 507B. The polymer layers 507A, 507B may comprise polybenzoxazole (PBO) and may be at least 10 microns thick. The conductive balls 305, 405A-405C, 515 may be placed on the redistribution lines 407A-407C, 513 that comprise a surface oxide layer at least 20 angstroms thick. The conductive balls 305, 405A-405C, 515 may comprise solder balls. The mold material 104, 403 may comprise an epoxy mold material. A partial cure of the mold material may be performed during the compression molding process, step 213.

While the invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

1. A method for semiconductor packaging, the method comprising:
bonding a semiconductor wafer to a support structure;
separating the wafer into a plurality of discrete die;
removing said plurality of discrete die from said support structure;
attaching at least a subset of said plurality of discrete die to a second support structure;
placing mold material in voids between said attached at least a subset of said plurality of discrete die utilizing a compression molding process, thereby generating a molded wafer;
removing said molded wafer from said second support structure;
forming a first dielectric layer on said at least a subset of plurality of discrete die and on said mold material;
depositing redistribution lines on said at least a subset of plurality of discrete die and said first dielectric layer;
forming a second dielectric layer on a native oxide layer that is on the deposited redistribution lines, where the native oxide layer has a thickness of at least 20 angstroms;
placing conductive balls on at least a subset of said redistribution lines; and
separating said molded wafer into plurality of molded packages.

2. The method according to claim 1, wherein said redistribution lines comprise copper.

3. The method according to claim 1, comprising planarizing said molded wafer utilizing a post-mold cure on a vacuum fixture after removing said molded wafer from said second support structure.

4. The method according to claim 3, comprising back-grinding said molded wafer after said post-mold cure.

5. The method according to claim 1, wherein said redistribution lines are electrically isolated utilizing the formed first and second dielectric layers, which comprise one or more polymer layers.

6. The method according to claim 5, wherein said one or more polymer layers comprise polybenzoxazole (PBO).

7. The method according to claim 5, wherein said one or more polymer layers have a thickness of more than 10 microns.

8. The method according to claim 1, wherein said placing conductive balls comprises placing said conductive balls on a native oxide layer having a thickness of at least 20 angstroms and that is on said redistribution lines.

9. The method according to claim 1, wherein said conductive balls comprise solder balls.

10. The method according to claim 1, wherein said mold material comprises an epoxy mold material.

11. A method for semiconductor packaging, the method comprising:
generating a plurality of molded semiconductor packages in a molded wafer process comprising:
bonding a semiconductor wafer to a support structure;
separating the wafer into a plurality of discrete die;
removing said plurality of discrete die from said support structure;
attaching a subset of said plurality of discrete die to a second support structure;
placing mold material in voids between said attached at least a subset of said plurality of discrete die utilizing a compression molding process, thereby generating a molded wafer;
removing said molded wafer from said second support structure;
planarizing said molded wafer;
forming a first dielectric layer on said subset of said plurality of die and on said mold material;
depositing redistribution lines on said die and said first dielectric layer;
forming a second dielectric layer on a native oxide layer that is on the deposited redistribution lines, where the native oxide layer has a thickness of at least 20 angstroms;
placing conductive balls on at least a subset of said redistribution lines; and
separating said molded wafer into said plurality of molded packages.

12. The method according to claim 11, wherein said redistribution lines comprise copper.

13. The method according to claim 11, wherein said planarizing comprises a post-mold cure on a vacuum fixture after removing said molded wafer from said second support structure.

14. The method according to claim 13, wherein said planarizing comprises back-grinding said molded wafer after said post-mold cure

15. The method according to claim 11, wherein said redistribution lines are electrically isolated utilizing the formed first and second dielectric layers, which comprise one or more polymer layers.

16. The method according to claim 15, wherein said one or more polymer layers comprise polybenzoxazole (PBO).

17. The method according to claim 15, wherein said one or more polymer layers have a thickness of more than 10 microns.

18. The method according to claim 11, wherein said placing conductive balls comprises placing said conductive balls on a native oxide layer having a thickness of at least 20 angstroms and that is on said redistribution lines.

19. The method according to claim 11, wherein said conductive balls comprise solder balls.

20. A method for semiconductor packaging, the method comprising:
generating a plurality of molded packages in a molded wafer process comprising:
attaching a plurality of discrete die to a support structure;
placing mold material in voids between said attached discrete die utilizing a compression molding process, thereby generating a molded wafer;
removing said molded wafer from said support structure;
forming a first dielectric layer on said attached discrete die and on said mold material;
depositing redistribution lines on said die and said first dielectric layer;
forming a second dielectric layer on a native oxide layer that is on the deposited redistribution lines, where the native oxide layer has a thickness of at least 20 angstroms;
placing conductive balls on at least a subset of said redistribution lines at locations that comprise a native oxide layer having a thickness of at least 20 angstroms; and
separating said molded wafer into said plurality of molded packages.
